(19) United States
(12) Patent Application Publication
(10) Pub. No.: US 2026/0358118 A1
(43) Pub. Date: Nov. 12, 2026

(54) METHOD AND SYSTEM FOR HIGH-PRECISION ALIGNMENT AND TRANSFER OF MICRODEVICES IN OPTOELECTRONIC MANUFACTURING

(71) Applicant: VueReal Inc., Waterloo (CA)

(72) Inventors: Gholamreza CHAJI, Kitchener (CA); John CRONIN, Jericho, VT (US)

(73) Assignee: VueReal Inc., Waterloo, ON (CA)

(21) Appl. No.: 19/527,353

(22) PCT Filed: Oct. 11, 2024
(86) PCT No.: PCT/IB2024/059999

§ 371 Date: Apr. 9, 2026

Related U.S. Application Data
(60) Provisional application No. 63/589,595, filed on Oct. 11, 2023.

(51) Int. Cl. G01B 21/04; B81C 99/00

(52) U.S. Cl. CPC G01B 21/042; B81C 99/0065; B81C 2203/051

(57) ABSTRACT

The invention discloses an advanced method for manufacturing optoelectronic system arrays, where microdevices are developed separately and then transferred into a system substrate. The invention discloses multiple embodiments, including distributed sacrificial reference points, real-time monitoring with various sensing technologies, laser-generated alignment marks, non-contact laser triangulation, and using polymers for marking to assess and correct alignment during each transfer stage dynamically. The invention further discloses methods, which may be AI based, for detecting and correcting errors caused by wear, environmental changes, load variability, and mechanical vibrations. In general, this system for pre-transfer calibration, monitoring, error detection, and compensatory adjustments enables precise and reliable integration of microdevices into optoelectronic systems, significantly enhancing alignment accuracy, stability, and reliability throughout the manufacturing process. The system can be further an AI-based calibration validation in a microdevice transfer system.

### CROSS-REFERENCE TO RELATED APPLICATIONS

This application claims priority to U.S. Provisional Patent Application No. 63/589,595 filed Oct. 11, 2023, which is hereby incorporated by reference herein in its entirety.

### FIELD OF THE INVENTION

The present disclosure relates to a method of measuring and correcting an alignment error during a microdevice transfer. The method further an AI-based calibration validation in a microdevice transfer system.

### SUMMARY

The present invention relates to a method to measure an alignment error, the method comprising: having a pattern of polymers on a system substrate, having an additional pattern under or around a polymer to facilitate measurement of alignment error, creating marks by a microdevice holder/substrate on the polymer, and using the location of markings relative to the polymer pattern or the additional pattern to calculate the alignment error.

The present invention relates to a for calibrating an alignment of microdevices during manufacturing, comprising, performing a pre-transfer calibration of an alignment tool, wherein an alignment reference is established between a microdevice holder and a system substrate, executing a test transfer involving sacrificial structures positioned on a microdevice substrate, wherein the said sacrificial structures are transferred to a test area on the system substrate, evaluating an alignment error based on a comparison of transferred sacrificial structure positions relative to predefined reference points on the system substrate, adjusting the alignment tool based on an alignment error determined from the said evaluation to correct any positional discrepancies between the microdevice holder and the system substrate and transferring the microdevices from the microdevice holder to the system substrate following the calibration, wherein the said transfer is performed using recalibrated alignment settings. The present invention relates to a method for monitoring and correcting an alignment during a microdevice transfer, comprising, verifying an initial position of microdevices on a microdevice holder relative to alignment marks on a system substrate, continuously a monitoring alignment during the microdevice transfer using real-time sensing data, wherein any deviation from an intended alignment, based on marks, is detected, identifying an alignment error based on discrepancies observed during the said monitoring, and determining corrective action to maintain an alignment accuracy, performing compensatory adjustments to a positioning of the microdevice holder or the system substrate to correct the said alignment error during transfer, and completing the transfer of the microdevices to the system substrate following said compensatory adjustments to enable precise positioning.

The present invention relates to a method for monitoring and correcting an alignment during a microdevice transfer, comprising, verifying an initial position of microdevices on a microdevice holder relative to alignment marks on a system substrate, continuously monitoring the alignment during the microdevice transfer process using real-time sensing data; detecting any deviations from the intended alignment by comparing the real-time positions of alignment marks on the microdevice holder and the system substrate, determining corrective actions to compensate for detected alignment errors during the transfer; performing compensatory adjustments to an alignment tool or positioning system based on the detected deviations to maintain a precise alignment, and completing the transfer of microdevices to the system substrate following said adjustments, enabling proper and accurate placement of all microdevices.

The present invention relates to method for an AI-based calibration validation in a microdevice transfer system, comprising, capturing real-time environmental and operational data using sensors, including temperature sensors, humidity sensors, load sensors, and accelerometers; performing sacrificial test transfers to establish alignment marks on the system substrate, using a machine learning model to compare the current position of alignment marks with reference positions, wherein the machine learning model identifies deviations indicating an incorrect or a degraded calibration, clustering alignment data to detect trends in a calibration accuracy over time, distinguishing between properly calibrated and degraded tool settings, triggering recalibration or maintenance procedures if the deviations exceed predefined thresholds, and continually updating an AI model using data collected from calibration validation steps to enhance predictive accuracy and improve alignment precision throughout a manufacturing process.

### BRIEF DESCRIPTION OF THE DRAWINGS

The preceding and other advantages of the disclosure will become apparent upon reading the following detailed description and upon reference to the drawings.

FIG. 1A shows an exemplary pattern of polymers 100 on the system substrate.

FIG. 1B shows the print/marking 104 created by the microdevice holder/substrate on the polymer.

FIGS. 2A and 2B show exemplary patterns for the polymers that can facilitate the accurate measurement of misalignment.

FIG. 3 shows an overall system method for error checking.

FIG. 4 describes a system that deploys a Step-by-Step Method for Error Correction and Fixing.

While the present disclosure is susceptible to various modifications and alternative forms, specific embodiments or implementations have been shown by example in the drawings and will be described in detail herein. It should be understood, however, that the disclosure is not intended to be limited to the particular forms disclosed. Instead, the disclosure covers all modifications, equivalents, and alternatives falling within the spirit and scope of an invention as defined by the appended claims.

### DETAILED DESCRIPTION

The invention pertains to an advanced manufacturing method for optoelectronic system arrays, focusing on integrating microdevices with a high degree of alignment precision. Instead of fabricating these microdevices directly on the system substrate, they are developed separately and then transferred to the substrate, which helps reduce manufacturing costs and enhance overall performance. Given the significant miniaturization of these devices (down to a few micrometers), achieving precise alignment is critical for the successful assembly of the array.

Traditional approaches rely on the inherent accuracy of positioning tools, which capture alignment marks on both the microdevice holder and the system substrate to adjust the relative positions accordingly. However, tool calibration tends to drift over time due to movement or environmental changes, leading to reduced alignment accuracy.

Tool calibration drift occurs because precision instruments used in manufacturing are susceptible to various mechanical and environmental influences that accumulate over time. For the manufacturing process described, even slight deviations can significantly impact alignment accuracy, especially when working with microdevices on the order of a few micrometers.

Several factors contribute to this drift, which can occur separately or together, which makes alignment complicated and requires enhancements to overcome these factors.

Mechanical Wear and Tear contribute to drift. Over time, the moving components of alignment tools, such as motors, actuators, and guide rails, can experience wear. This wear leads to small but significant variations in the movement, which reduces positioning accuracy. Microdevices require nanometer-level precision; even minor imperfections in the mechanical path can cause misalignments.

Thermal Expansion and Contraction contribute to drift. Manufacturing environments can be affected by temperature fluctuations. Metals and other materials expand or contract with temperature changes, which causes variations in the tool's components and affects calibration. Even a slight temperature shift can change the relative positioning of the microdevice holder and the system substrate, resulting in alignment errors.

Vibration and Mechanical Disturbance contribute to drift. The alignment tools and positioning systems can be affected by vibrations from surrounding equipment or infrastructure. Vibrations, even those that are not directly perceptible, can lead to tiny shifts in the positioning apparatus, causing cumulative misalignment issues during the transfer process.

Environmental Factors contribute to drift. Changes in ambient humidity can also play a role. Certain materials may absorb moisture, subtly changing their dimensions and contributing to calibration drift. Moreover, air currents or pressure differences can interfere with the stability of the machine's environment, potentially leading to slight misalignments.

Tool Load Variability contributes to drift. When different batches of microdevices are loaded, the weight and distribution may vary slightly. These changes can influence the behavior of mechanical parts, especially if the system wasn't designed to handle such variability in a calibrated way. As new microdevices are loaded for transfer, the added weight can shift the tools out of their previously calibrated state.

Material Fatigue contributes to drift. Repeated use of alignment tools can also lead to material fatigue. This affects the structural rigidity of components, leading to minor deformations over time. These changes are often subtle but can accumulate, gradually losing the precision required for accurate alignment.

Tool Calibration Errors contribute to drift. The tools require periodic recalibration, and improper or delayed calibration can result in misalignment. If the recalibration is not conducted precisely or neglected, the system's ability to maintain alignment accuracy will degrade over time.

Given these potential causes of drift, it's challenging to maintain the high level of precision required for integrating microdevices into substrates. This is why the invention proposes ongoing dynamic calibration methods, like test transfers, to continually correct for any inaccuracies that develop, ensuring the alignment is consistently within acceptable limits for high-performance optoelectronic systems.

This invention introduces methods to calibrate alignment tools dynamically by performing pre-transfer calibration steps. These steps include test transfers of sacrificial structures or creating marks on a polymer layer to detect alignment errors before actual micro device transfer. Adjusting tool parameters (like temperature, pressure, or light conditions) based on detected errors ensures more reliable alignment. Additionally, by incorporating sacrificial features or polymer markings, the invention offers adaptable ways to monitor and correct misalignments, ultimately improving optoelectronic systems' integration quality and reliability.

A method of manufacturing an optoelectronic system array is to develop optoelectronic devices separately and transfer the microdevices into the system substrate. To reduce the cost and improve performance, the microdevices are reduced in size significantly (a few micrometers). Therefore, properly integrating these microdevices into the substrate requires significant alignment accuracy.

In traditional approaches to aligning microdevices with the system substrate, the process relies heavily on the accuracy of positioning tools to ensure precise alignment. The system employs alignment marks on the microdevice holder (or substrate) and the system substrate, which serves as reference points for positioning. Typically, cameras are used to capture these alignment marks. Here, the alignment mark in the microdevice holder/substrate is captured by a camera, and the alignment mark on the system substrate is also captured. The position of the microdevices relative to the system substrate is calculated, and the position of the two substrates is adjusted accordingly. The challenge is the tool calibration due to movement and other factors may change, so the alignment accuracy may not be enough for such a process.

Still, other sensing technologies, such as laser triangulation sensors, optical encoders, or interferometric sensors, can also detect and map the alignment features on both substrates. These sensors gather precise spatial data, which is then processed to calculate the offset between the microdevice holder and the system substrate, enabling necessary adjustments for proper positioning.

Maintaining this level of accuracy is challenging due to several potential causes of drift and deviation, each of which can affect the alignment process. The system must address these issues effectively in real time.

Mechanical wear and tear on components such as motors, actuators, and guide rails can lead to inaccuracies over time, affecting the precise movement of the positioning system. When the alignment marks on the microdevice holder and substrate are detected by optical sensors (e.g., laser triangulation sensors), any deviation from their intended position indicates potential mechanical drift. The system captures these deviations, which are then adjusted incrementally to adjust the tool path, compensating for wear-related inaccuracies. This dynamic correction allows the system to maintain precise alignment, even as components experience degradation.

Thermal expansion and contraction also introduce drift, as temperature changes can cause structural elements to expand or contract, slightly altering the positioning of the microdevice holder and substrate. In such cases, thermal sensors are used to monitor the temperature of the tool's components. If temperature changes are detected, the system anticipates the impact on the alignment marks. For example, interferometric sensors can measure any resulting positional shifts. If discrepancies in alignment are detected, the system recalculates positioning parameters to compensate for thermal-induced deviations before proceeding with the microdevice transfer.

Vibrations and mechanical disturbances can also introduce misalignments, mainly during the alignment or transfer phase. To detect and mitigate the impact of vibrations, the system employs accelerometers that continuously monitor vibration levels. If vibrations exceed acceptable thresholds, the system pauses the alignment process and waits until the vibrations subside. After stabilization, the alignment marks are detected again using precise sensors to ensure accuracy before proceeding. This ensures adjustments are based on stable alignment readings, preventing cumulative errors caused by transient vibrations.

Environmental factors, such as humidity, may influence the alignment process by affecting materials used, such as polymers on the system substrate that expand or contract with moisture. The system uses humidity sensors to monitor environmental conditions continuously in this scenario. Optical encoders or laser-based sensors then detect changes in the positions of alignment marks. If the alignment marks on the polymer substrate have shifted due to humidity effects, the system recalculates and corrects the alignment parameters accordingly. Environmental controls such as humidity regulators may also be activated to maintain optimal conditions.

Load variability can also affect the alignment process. When the number of microdevices loaded onto the microdevice holder changes, it may result in slight deformation or movement of the microdevice holder, leading to alignment errors. Load sensors integrated into the holder detect changes in weight, while the relative positions of the alignment marks are continuously monitored using sensors like interferometers. If discrepancies are observed, the system recalculates the alignment to compensate for the deflection or changes in the microdevice holder's position due to varying loads. The system may also initiate a balancing procedure to reduce the effects of uneven loading.

Material fatigue over time leads to deformation of the structural components, affecting alignment precision. Strain gauges embedded in the tool's supporting structures monitor any deformation and alert the system if detected. The system then uses these readings, alongside positional data from optical sensors, to apply corrective offsets to maintain alignment accuracy. If deformation exceeds acceptable limits, the system suspends the alignment process and calls for maintenance before recalibrating and resuming operations.

Tool calibration errors can also impact the reliability of the alignment process. To validate calibration, the system periodically performs test transfers using sacrificial structures. During these tests, the system uses sensors—such as laser scanners or optical encoders—to detect the positions of transferred marks on the system substrate. If discrepancies are detected, recalibration routines are initiated, and adjustments are made to ensure that the tool maintains its expected baseline performance.

In all these scenarios, the expanded alignment system utilizes various sensing technologies beyond cameras—such as laser triangulation sensors, interferometric sensors, optical encoders, and accelerometers—to capture precise alignment mark positions and environmental data. This information is processed in real-time to detect deviations, determine the causes of drift, and apply appropriate corrections. Test transfers, continuous feedback from sensors, and dynamic adjustments allow the system to effectively manage different sources of drift and maintain high alignment precision, thereby ensuring reliable integration of microdevices into optoelectronic systems. The position of the microdevices relative to the system substrate is calculated, and the position of the two substrates is adjusted accordingly. The challenge is the tool calibration due to movement and other factors may change, so the alignment accuracy may not be enough for such a process.

In one embodiment, the test transfer uses multiple distributed sacrificial reference points across the microdevice holder and system substrate. Instead of transferring all sacrificial structures to a single test area, these reference points are distributed across different substrate regions to identify variations caused by localized factors. This allows the system to detect and correct alignment errors due to specific areas undergoing different effects, from thermal expansion, mechanical wear, or uneven loading. Each region-specific correction helps to ensure that alignment precision is maintained across the entire substrate rather than relying solely on a single global adjustment.

In one embodiment, a test transfer is done before a defined number of transfers, and the alignment error is used to calibrate the tool. Here, there are some sacrificial structures in microdevice substrates that are transferred to a test area. The camera picks the error in the transfer and adjusts the tools to correct the error. This process requires a test area on the main substrate and also sacrificial structure on the microdevice substrate. In addition, suppose the transfer process requires all the microdevices in the microdevice holder/substrate to be transferred simultaneously. In that case, this method may not be effective, as loading new microdevices can move the tool out of calibration.

Another embodiment involves a dynamic test transfer process utilizing real-time feedback from various types of sensors, such as interferometric sensors and optical encoders, instead of relying only on static sacrificial structures. During the actual transfer process, these sensors continuously monitor the positions of the alignment marks. If a misalignment is detected at any point, the system pauses and recalculates the necessary corrections before continuing the transfer. This real-time recalibration ensures that even if factors such as mechanical wear or temperature variations occur during the process, the alignment remains within acceptable accuracy limits.

In another embodiment, sacrificial structures are replaced by laser-generated alignment marks on a temporary polymer layer coated on the system substrate. Before transferring the microdevices, the system uses a laser to create alignment patterns on this polymer layer, which can then be analyzed for alignment accuracy. The use of a laser allows the test marks to be generated without physically transferring microdevices, thus reducing potential damage or calibration loss due to handling. Additionally, since the polymer layer is removable, it can be easily eliminated before the microdevice transfer, ensuring that the substrate remains uncontaminated.

In one embodiment, a non-contact method, such as laser triangulation, assesses alignment accuracy before actual transfer. Instead of transferring sacrificial structures, laser triangulation sensors scan alignment marks on the microdevice holder and the system substrate. The laser's reflections are used to determine if the alignment is correct, allowing any adjustments before physical contact. This non-contact testing approach minimizes wear on the system. It reduces the chance of calibration drift caused by direct interaction with the sacrificial materials, improving the system's reliability over time.

Another embodiment involves using a heat-sensitive material on the system substrate for test transfers. Before transferring the microdevices, the alignment system performs a simulated transfer in which the microdevice holder applies minimal heat to a temperature-sensitive polymer layer on the system substrate. This polymer changes color in response to heat, providing visual feedback on the alignment position. The system can detect misalignments by analyzing the heat marks and adjusting accordingly before proceeding with the actual micro device transfer. This embodiment allows for sacrificial test areas without physical material transfer, which is particularly useful in cases where transferring new microdevices could potentially move the tool out of calibration.

The alignment system utilizes a holographic projection in another embodiment to create virtual alignment marks on the microdevice holder and the system substrate. The holographic system projects alignment grids that are captured and analyzed by a high-resolution sensor array. This allows for precise virtual alignment verification before the physical transfer takes place. Using holographic markers, the system can assess alignment accuracy without any physical contact, thus eliminating the risks of transferring sacrificial structures or causing tool calibration drift due to handling.

Finally, the system performs simultaneous calibration using load-distributed sacrificial transfers in one embodiment. Instead of transferring all microdevices simultaneously, this approach transfers only specific sections as sacrificial structures to determine load-induced errors. This is followed by recalibrating the positioning system to account for load variability before attempting the complete transfer of all microdevices.

The system can incorporate differential strain gauges to monitor load distribution precisely during the partial sacrificial transfer phase. These strain gauges are strategically positioned on the tool and substrates to detect any deformation or deflection due to uneven transfer loading. The system can identify areas where load-related shifts are causing misalignment by gathering detailed feedback from these strain gauges. Once detected, the system performs real-time recalibration to compensate for these load-induced errors before proceeding with the complete transfer of all microdevices. This ensures that stable calibration is maintained and that each microdevice is accurately transferred to its designated position, enhancing the overall reliability and precision of the manufacturing process. This embodiment allows the system to address load variability issues dynamically and ensures that alignment precision is not compromised by unexpected load-induced shifts during full-scale transfer operations.

In another related embodiment, the test transfer is done solely to create prints (or marks) on a specially defined polymer layer on the system substrate before the actual transfer of the microdevices. This test transfer aims to determine alignment accuracy by analyzing the print locations. These polymer marks serve as a visual indication of whether the microdevice positioning is correct. Notably, the polymer used in these test areas does not have potent bonding agents, meaning it cannot separate microdevices from the microdevice substrate. This design allows the microdevices to create the marks without adhering to the substrate. In one related embodiment, to create marks, the polymer material used in the test areas do not have strong bonding agents and cannot separate microdevices from the microdevice substrate. In this case, the microdevices themselves are used to create the marks. In another related embodiment, the transfer parameters are adjusted so that the microdevices do not stick to the system substrate strongly. Here, the test area can be the same area as the actual transfer area. The process parameters that can be adjusted are temperature, pressure or lighting conditions. Here, the print/marks can be generated by the microdevices on the microdevice holder/substrate, or there can be extra features in the microdevice holder/substrate creating the print.

The transfer parameters, such as temperature, pressure, or lighting conditions, are adjusted to ensure that the microdevices do not bond strongly to the polymer layer. In this way, the test transfer can be performed without causing any permanent attachment of microdevices to the substrate. The test area for these prints can even coincide with the intended transfer area, meaning that recalibration can be performed on the same substrate without additional test zones. By adjusting critical parameters like temperature to reduce adhesive forces, pressure to control contact level, or lighting conditions that may influence polymer characteristics, the system can simulate the actual transfer environment while mitigating bonding risks. This approach not only allows for precise determination of any alignment error but also offers the flexibility to conduct recalibrations on the active area, optimizing the efficiency and accuracy of the overall transfer process.

In another related embodiment, the marking exists on the microdevice holder/substrate and is transferred to the system substrate. The marking can be polymer placed on the microdevice substrate or on a set of selected microdevice substrates that can be transferred into the system substrate during the test transfer. The location of transferred marks can be used to extract the misalignment error.

In another related embodiment, the marking is pre-existing on the microdevice holder or substrate and is transferred directly to the system substrate during the test process. These markings may be a polymer layer or other material applied to the microdevice substrate in a defined pattern, either covering individual microdevices or applied uniformly across a set of selected microdevice substrates. These polymer markings are physically imprinted onto the system substrate during the test transfer phase. This method allows for a precise one-to-one mapping between the microdevice holder and the target area.

The system can accurately determine any misalignment during the test transfer by analyzing the location of these transferred markings relative to their intended marked positions. This information is then used to calculate the misalignment error, which helps the system determine the necessary corrections to achieve optimal alignment. The positioning needs adjustment if the transferred marks do not precisely match the expected reference points. The discrepancies can arise from mechanical factors, environmental influences, or other variables affecting the transfer process.

Furthermore, this embodiment is highly beneficial in allowing alignment to be assessed across the total area of the system substrate without the need for separate sacrificial structures. The markings act as both alignment indicators and calibration aids, providing direct physical evidence of how accurately the system positions the microdevice substrates. This approach can also be extended by varying the material properties of the polymer marking, such as using different colors, reflective qualities, or thicknesses, which can enhance the precision of error detection through automated vision systems or other sensing technologies.

Once the misalignment errors are extracted by comparing the actual positions of the transferred marks to their expected positions, the system can recalibrate the alignment tools accordingly. This recalibration may involve adjusting motor steps, applying compensatory offsets, or modifying environmental conditions such as temperature and pressure to correct the alignment before the micro device transfer. This method provides a straightforward, direct feedback mechanism to improve alignment accuracy and stability during the critical transfer stages, significantly enhancing the reliability of the overall manufacturing process.

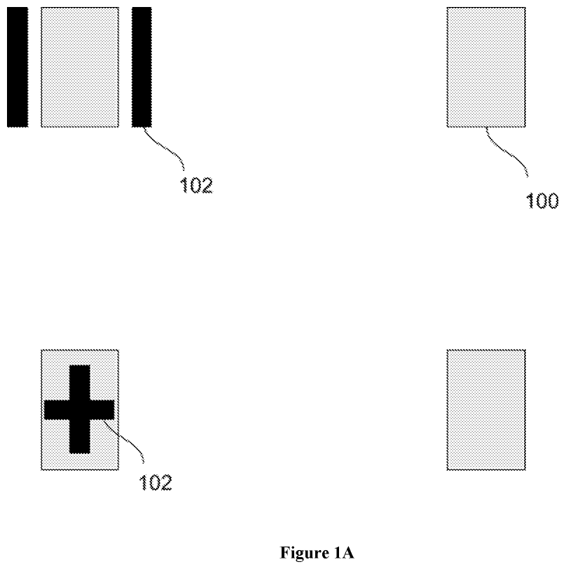

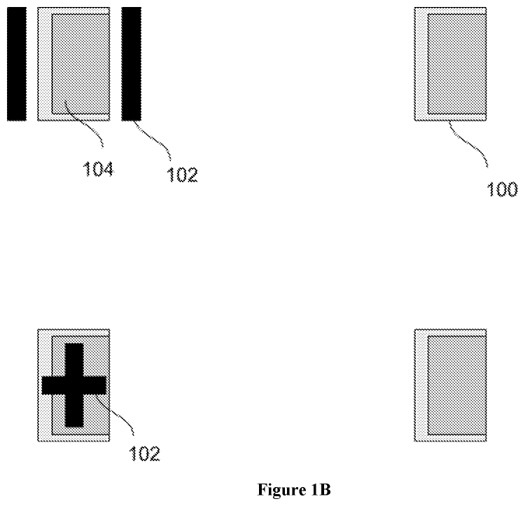

FIG. 1A shows an exemplary pattern of polymers 100 on the system substrate. In one embodiment, another pattern 102 is under or around the polymer to facilitate the measurement of alignment error. In another related embodiment, the polymer is a continuous film on top of defined pattern 102 that can be used for measuring the alignment error. The pattern can have different shapes and configurations. FIG. 1A shows two examples of the pattern for polymer 100 and extra measurement pattern 102.

FIG. 1B shows the print/marking 104 created by the microdevice holder/substrate on the polymer. Here, the location of markings 104 relative to the polymer pattern 100 or the extra pattern 102 can be used to calculate the misalignment error.

The polymer can be eliminated in an embodiment where the marking exists on the microdevice. In one related embodiment, the polymer can be adhesive to hold the marking.

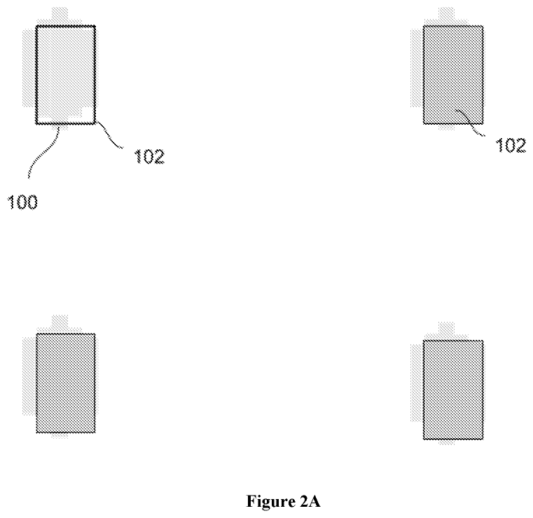

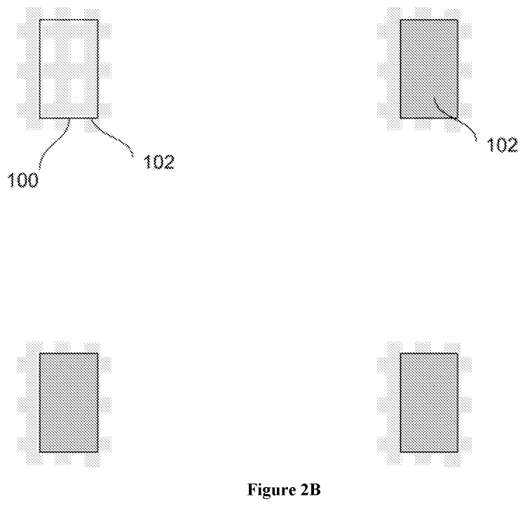

FIGS. 2A and 2B show exemplary patterns for the polymers that can facilitate the accurate measurement of misalignment.

Tool calibration drift in optoelectronic manufacturing can arise from various mechanical and environmental factors, each contributing to inaccuracies in the alignment of microdevices. Mechanical wear and tear of tooling, such as motors, actuators, and linear guides, introduces movement inaccuracies over time. Components like ball screws or guide rails wear down, leading to slight deviations in the travel path. For instance, consider FIG. 1A, where the alignment marks on the microdevice holder and system substrate are used to determine precise alignment. Due to mechanical wear, the microdevice holder might over- or under-travel slightly, which results in a mismatch between the alignment marks as seen by the camera. This misalignment is then calculated, and the system adjusts the relative positions. However, because of the degradation in mechanical accuracy, the correction may be insufficient, leading to an imperfect transfer of the microdevice.

Thermal expansion and contraction also play a significant role in causing calibration drift. The structural components of the tool, such as the base plate or mounting frames, expand or contract with temperature fluctuations, thereby altering the precise positioning of the alignment system. Imagine FIG. 1B, where microdevices are transferred onto a polymer surface marked with alignment references. If the ambient temperature changes, the microdevice holder may expand or contract, which causes a shift in the alignment marks' relative positions. The camera detects these marks, but due to the physical changes in the microdevice holder or substrate, the calculated alignment may be offset, necessitating repeated adjustments. This scenario is exacerbated by a lack of proper thermal management, making maintaining the original accuracy during alignment difficult.

Vibrations and mechanical disturbances from nearby equipment can also introduce calibration drift. Even minor vibrations from nearby operations can cause micro-movements within the alignment system, particularly during mark capturing. In FIG. 1A, the vibration might cause a shift right as the camera captures the alignment marks on the microdevice holder and system substrate. This would result in an incorrect reading of their relative positions, leading the system to adjust the microdevice holder before transferring incorrectly. The result is a drift that accumulates over time, affecting overall alignment precision.

Environmental factors like humidity further contribute to drift. For example, polymers used for marking on the system substrate, as shown in FIG. 1A, may absorb moisture from the surrounding environment. This slight change in the material's dimensions results in discrepancies between the original alignment mark positions and those captured during the alignment process. As the microdevice holder aligns with these altered marks, the system calculates an incorrect relative position, which leads to the misalignment of the transferred microdevice. Such discrepancies are particularly problematic when the dimensions involved are on the order of micrometers.

Load variability in the tooling is another contributor to drift. When the number of microdevices loaded on the microdevice holder varies, it changes the weight and load distribution on the positioning system, which can influence the system's accuracy. FIG. 1B shows an alignment scenario where microdevices must be transferred simultaneously. If the load changes from one batch to another, the tool holding the microdevice may deflect slightly, affecting the alignment of the marks relative to the system substrate. The camera detects this misalignment, but the subsequent adjustment may not fully correct the error due to the variable impact of load weight on the positioning accuracy.

Material fatigue is another factor affecting alignment precision over repeated use. Continuous operation can gradually deform the structural supports of the positioning system, altering their rigidity and leading to inaccuracies. For example, FIG. 1A shows alignment marks that must be repeatedly used over many operations. Due to fatigue, the base holding the system substrate may subtly warp, shifting the alignment marks' positions. The captured alignment marks, even if recalculated by the system, will not provide the same accuracy as before because of this structural deformation. This results in a gradual degradation in alignment quality unless corrective measures are implemented.

Finally, tool calibration errors themselves play a crucial role. Periodic recalibration is needed to maintain precision, but improper or delayed calibration can introduce drift. Referring to FIGS. 2A and 2B, if the calibration process is not precise, the alignment marks used during test transfers may be captured inaccurately, leading to errors during actual microdevice placement. Sacrificial test markings designed to identify such drift might become inaccurate due to calibration issues, causing the system to apply incorrect corrections and ultimately leading to persistent misalignments.

The invention addresses these drift forms in all these scenarios by introducing methods such as pre-transfer test steps, sacrificial structures, and alignment marks using polymers. These approaches allow for dynamic calibration, enabling the system to adjust for inaccuracies in real time based on feedback from test marks or practice transfers. This significantly mitigates the effects of drift, ensuring higher alignment accuracy and reliability in integrating microdevices into optoelectronic systems.

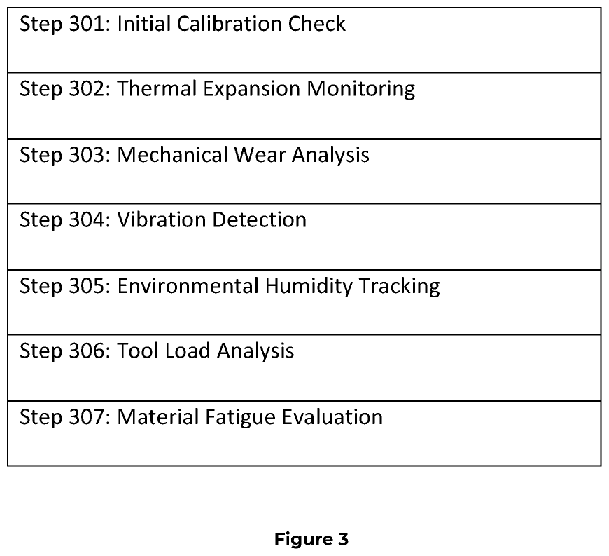

FIG. 3 shows an overall system method for error checking. This system method aims to establish a routine that identifies potential sources of alignment drift due to different error scenarios. This involves capturing real-time environmental and operational data, performing test transfers, and using monitoring tools to detect deviations from expected performance.

Step 301 does the Initial Calibration Check. Start each shift or batch by performing a baseline calibration check. Use alignment marks on the microdevice holder and system substrate as reference points. In this step, the system verifies that it matches the original alignment settings to ensure no initial discrepancies are present.

Step 302 performs a Thermal Expansion Monitoring analysis. Step 302 utilizes temperature sensors on the tool's structural components. Step 302 captures temperature data continuously. If significant temperature changes occur, initiate a thermal compensation check to adjust the expected positions of the alignment marks on the microdevice holder and substrate.

In one embodiment, Step 302 can use an AI system to enhance the results, for instance The AI implementation for Step 302 involves using a machine learning algorithm, such as a Convolutional Neural Network (CNN), to enhance the accuracy and efficiency of the initial calibration check during the microdevice alignment process. The CNN is trained to recognize and compare alignment marks on the microdevice holder and system substrate, allowing the system to detect any discrepancies and to verify that the alignment matches the original calibration settings.

The data used for the AI implementation includes high-resolution images of alignment marks captured by an optical sensor or camera. These images contain detailed information about the spatial position, orientation, and quality of the alignment marks. During each calibration check, new images are collected and fed into the trained CNN model, which compares these images to the reference dataset to determine whether the current alignment meets the required precision standards.

An example result from this AI implementation may be a precise measurement of alignment offset, indicating whether the microdevice holder and the system substrate are correctly aligned. The CNN might output a confidence score along with the measured offsets, indicating the level of certainty that the current alignment is accurate. If the confidence score is below a set threshold, the system identifies that recalibration is required, and provides exact metrics for correcting the alignment.

These results are then fed forward to improve the overall system by allowing dynamic adjustments to be made in real time. The output from the CNN, including the alignment offset and confidence score, is used to update the positioning commands for the actuators controlling the microdevice holder. This ensures that any deviations detected during the initial calibration are corrected immediately, reducing the chance of misalignment in later stages of the microdevice transfer. Moreover, the data collected from each calibration run can be added to the training dataset, allowing the CNN to learn from past deviations and continually improve its accuracy and predictive power over time.

An example table of results that could be generated by the AI implementation might look like this:

| | Initial | Correction | Confidence | Recalibration |
|---|---|---|---|---|
| Batch | Offset | Applied | Score | Needed |
| Number | (μm) | (μm) | (%) | (Yes/No) |
| Batch 101 | 2.5 | 2.4 | 95 | No |
| Batch 102 | 5.1 | 5.0 | 85 | Yes |
| Batch 103 | 0.8 | 0.7 | 98 | No |
| Batch 104 | 6.3 | 6.2 | 82 | Yes |

In this table, “Initial Offset” represents the misalignment detected by the CNN during the calibration check, while “Correction Applied” indicates the adjustment made by the system based on the AI's output. The “Confidence Score” reflects how certain the AI is about its findings, and “Recalibration Needed” indicates whether a recalibration was deemed necessary to maintain alignment accuracy. This table can be used by operators and engineers to monitor the consistency and reliability of the alignment process, and to identify patterns in the calibration data that might indicate areas for further improvement in the system setup. The “Confidence Score” is a numerical measure, typically in percentage form, that indicates how sure the AI algorithm is about the accuracy of the detected alignment between the microdevice holder and the system substrate. Physically, the AI is evaluating factors such as the quality, clarity, and consistency of the captured alignment marks, as well as how well these marks match their expected positions compared to the reference dataset.

Several physical elements contribute to adjusting the confidence score such as Clarity of Alignment Marks: The AI assesses the sharpness and visibility of the alignment marks. If the marks are blurry or partially obstructed, the confidence score decreases because the algorithm becomes less certain that it can determine the precise position of those marks accurately.

Another example is Positional Discrepancy. The physical offset between the alignment marks on the microdevice holder and the system substrate also influences the confidence score. If the marks are well aligned with minimal deviation from their reference positions, the confidence score will be high. Conversely, larger positional discrepancies lead to lower confidence, signaling a higher likelihood of misalignment.

Another example is Environmental Factors. Conditions like lighting, vibrations, or even temperature variations can affect the quality of the captured images of alignment marks. If these environmental influences introduce noise or inconsistencies, the AI reduces the confidence score due to the increased difficulty in accurately assessing the alignment.

Another example is Consistency Across Reference Points. The AI might also use multiple alignment marks distributed across the substrate to assess overall consistency. If the relative alignment between multiple marks is consistent, the confidence score is higher. If there are inconsistencies, indicating a potential misalignment or uneven drift, the confidence score is reduced.

These physical evaluations—sharpness of alignment marks, positional discrepancies, environmental stability, and consistency across multiple reference points—all play a role in determining how certain the AI is about its assessment. If the AI is not confident in the alignment accuracy, it will signal the need for recalibration to ensure the system maintains the necessary precision for the microdevice transfer.

Step 303 performs a Mechanical Wear Analysis. In step 303, the system performs a self-diagnostic on motors, actuators, and guide rails to assess wear. The system compares movement parameters against known values from previous sessions. The system uses built-in sensors to monitor positioning accuracy in real-time. If mechanical wear is detected, trigger an alert for maintenance or realignment.

The AI implementation for Step 303 involves the use of a machine learning algorithm, such as a Long Short-Term Memory (LSTM) neural network, to analyze mechanical wear in the system's components, including motors, actuators, and guide rails. LSTMs are well-suited for this application because they can process time-series data, making them effective at detecting patterns over extended operational periods that indicate gradual wear or emerging mechanical issues.

A Long Short-Term Memory (LSTM) neural network is a type of Recurrent Neural Network (RNN) specifically designed to process sequential data and address challenges like the vanishing gradient problem that traditional RNNs face. The vanishing gradient problem occurs when the gradients used during training become very small, causing the model to stop learning. LSTMs overcome this by incorporating a memory cell and several gates—input, output, and forget gates—that regulate information flow. These gates determine which information is kept, updated, or discarded, allowing LSTMs to maintain long-term dependencies effectively.

LSTMs are particularly useful for sequential tasks, such as time series prediction, speech recognition, and machine translation, where it is important to learn the relationships between different points in time. Unlike traditional RNNs, LSTMs can remember information over long sequences, making them powerful for tasks where temporal context matters. The “vanilla” LSTM architecture, which includes these gates, is still widely used due to its effectiveness at capturing long-term patterns and handling complex sequential data.

The LSTM's strength lies in its ability to maintain relevant information across thousands of timesteps, making it ideal for problems that involve long-term dependencies. For example, LSTMs are often used in language modeling, where they help predict words based on a long history of context, or in robot control, where the system needs to learn actions over a sequence of movements. The architecture of LSTMs, specifically the gating mechanism, helps them regulate the input and output information in a way that supports both remembering and forgetting, which is crucial for maintaining context in long-term sequences without overwhelming the network's capacity.

By effectively managing what information is remembered or discarded, LSTMs maintain stable learning even for long sequences, making them suitable for many applications involving time-based data, such as speech recognition, handwriting recognition, and video analysis. They are also used in sequence-to-sequence tasks like translating one language to another, where the model reads an input sequence and generates a corresponding output sequence by processing the context throughout the entire input.

The data used for this AI implementation comes from built-in sensors that continuously monitor the positioning accuracy and movement parameters of the motors, actuators, and guide rails. This data includes variables such as motor speed, torque, actuator travel distances, vibration levels, and positional deviations. Historical data from previous sessions, where the system was functioning without any wear-induced issues, is also utilized as a reference point for comparison.

An example result generated by the LSTM model could be the detection of a trend indicating that the actuator is moving more slowly over time, suggesting potential mechanical resistance or degradation. The LSTM may output a prediction showing an increasing deviation in actuator movement compared to its expected behavior, which can be interpreted as a warning of developing wear. Based on this prediction, the system triggers an alert indicating the need for maintenance or realignment to prevent further deterioration or potential failure.

These results can be fed forward into the entire system to make real-time adjustments and improve reliability. For example, if mechanical wear is detected early, the system can automatically schedule a maintenance window or adjust operational parameters, such as reducing actuator speed or modifying load distribution to minimize stress on worn components. The predictive nature of the AI model also helps optimize maintenance schedules, allowing the system to carry out preventive measures instead of waiting for a failure, thereby reducing downtime and improving overall system efficiency.

An example table of results that the AI could produce might look like this:

| | | | Wear | Maintenance |
|---|---|---|---|---|
| | | Deviation | Prediction | Alert |
| | Parameter | Detected | Confidence | Triggered |
| Component | Analyzed | (%) | (%) | (Yes/No) |
| Motor 1 | Speed | 7 | 90 | No |
| Actuator 2 | Travel | 12 | 85 | Yes |
| | Distance | | | |
| Guide Rail 1 | Vibration | 5 | 88 | No |
| | Level | | | |
| Actuator 3 | Positioning | 15 | 92 | Yes |
| | Deviation | | | |

In this table, “Deviation Detected” indicates how much a particular movement parameter has diverged from its baseline or expected value. The “Wear Prediction Confidence” shows the level of certainty that the AI has in its prediction of wear-related issues. “Maintenance Alert Triggered” specifies whether a maintenance action has been recommended based on the detected deviation and confidence level. This table helps the system operators understand which components are showing signs of wear and allows them to plan maintenance accordingly, ultimately helping to extend the lifespan of the equipment and maintain optimal alignment accuracy.

Step 304 performs Vibration Detection analysis. Step 304 employs accelerometers on the system to detect vibrations—step 304 monitors for vibrations exceeding set thresholds during the alignment phase. In Step 304, the system performs pause alignment procedures if a vibration event is detected and recalibrates once stabilized.

The AI implementation for Step 304 uses a machine learning algorithm, such as a Decision Tree Classifier, to analyze vibration data during the alignment process. A Decision Tree is suitable for this application because it can classify events based on specific thresholds and rules, such as vibration levels that exceed a set limit, thereby allowing for quick decision-making regarding whether to continue, pause, or recalibrate the alignment process.

The data used for this AI implementation comes from accelerometers attached to various parts of the alignment system. This data includes real-time vibration readings, such as acceleration values along different axes (X, Y, Z), frequency of vibration events, and the duration of each event. Historical data with previously known instances of acceptable versus problematic vibration levels is used to train the model. This helps the Decision Tree learn which specific conditions indicate excessive vibration that requires intervention.

An example result from this AI analysis could be a classification of a vibration event as either “Normal” or “Excessive.” For instance, if the accelerometer readings exceed a predefined threshold, the Decision Tree may classify the event as “Excessive” and trigger an action to pause the alignment procedure. The system then waits until the vibrations stabilize before recalibrating and resuming the alignment. By classifying vibration events, the system can prevent the alignment process from proceeding under conditions that would likely lead to misalignment or damage to the components.

These results are used to feed forward improvements in the entire system by optimizing the alignment process based on vibration data. If the AI model consistently identifies certain environmental conditions that lead to excessive vibrations, adjustments can be made to the operating environment, such as reducing the speed of motors or adding damping materials to reduce the occurrence of such events. Additionally, the vibration data and classification results can be logged and analyzed over time to identify patterns, allowing for preventive measures to be implemented. For instance, if certain times of day or machinery setups are associated with higher vibrations, the system can adjust its operational schedules accordingly to minimize downtime.

An example table of results that the AI could produce might look like this:

| | Vibration | | | Recalibration |
|---|---|---|---|---|
| | Level | | Action | Triggered |
| Timestamp | (m/s²) | Classification | Taken | (Yes/No) |
| 2024-09-30 | 0.8 | Normal | Continue | No |
| 10:05:23 | | | | |
| 2024-09-30 | 1.5 | Excessive | Pause | Yes |
| 10:10:15 | | | Alignment | |
| 2024-09-30 | 0.6 | Normal | Resume | No |
| 10:12:50 | | | Alignment | |
| 2024-09-30 | 2.0 | Excessive | ause & | Yes |
| 10:20:30 | | | Recalibrate | |

In this table, “Vibration Level” represents the intensity of the detected vibrations, “Classification” indicates whether the vibration level was within acceptable limits, and “Action Taken” reflects what action the system decided to take based on the AI analysis. “Recalibration Triggered” indicates whether a recalibration step was initiated to ensure alignment accuracy.

This structured information helps operators and system engineers understand the effect of vibrations on the alignment process and make informed decisions to minimize their impact, ultimately leading to improved system performance and reliability.

Step 305 performs an Environmental Humidity Tracking. Step 305 uses humidity sensors to monitor environmental changes. Step 305 tracks polymer deformation by comparing previous alignment marks on polymer surfaces with current images captured by the camera. Step 3045 then logs the deviations to determine if humidity influences the alignment.

The AI implementation for Step 305 uses a regression algorithm, such as a Support Vector Regressor (SVR), to analyze and predict the impact of environmental humidity on the alignment accuracy of microdevices. SVR is particularly effective for this application because it can model the relationships between environmental factors, such as humidity levels, and the extent of materials deformation, providing a quantitative measure of how changes in humidity affect the alignment process.

The data used for this implementation comes from multiple sources. Humidity sensors provide continuous real-time readings of environmental humidity, and high-resolution images from cameras capture the current state of alignment marks on the materials (e.g. polymer) surfaces. Historical data, including humidity levels, images of polymer deformation, and corresponding alignment deviations, are used to train the SVR model. This historical dataset provides a baseline that allows the AI model to understand how changes in humidity are correlated with misalignment caused by polymer deformation.

An example result produced by this AI implementation could be a prediction of Materials (e.g. polymer) deformation based on current humidity readings, indicating the potential misalignment that might occur as a result. For instance, the SVR model might predict that at a humidity level of 75%, there is a high likelihood of deformation leading to a 3-micrometer deviation from the ideal alignment. This result helps the system decide whether corrective actions, such as adjusting alignment parameters or initiating a recalibration, are needed to counteract the potential impact of humidity-induced deformation.

The results of this analysis are fed forward to improve the entire system by adjusting the environmental control measures or by adapting the alignment calibration in real time. For example, if the SVR model predicts significant deformation at certain humidity levels, the system can proactively trigger dehumidifiers to reduce the humidity or alter the alignment configuration to compensate for the predicted deformation. Over time, the predictive model can be improved by continually updating it with the latest humidity and deformation data, leading to better forecasts and more accurate alignment maintenance. This approach not only prevents misalignments but also reduces downtime by addressing potential issues before they affect the production process.

An example table of results produced by this AI implementation might look like this:

| | | | Alignment | |
|---|---|---|---|---|
| | Humidity | Predicted | Deviation | Recalibration |
| | Level | Deformation | Detected | Triggered |
| Timestamp | (%) | (μm) | (μm) | (Yes/No) |
| 2024-09-30 | 60 | 0.5 | 0.6 | No |
| 09:30:10 | | | | |
| 2024-09-30 | 72 | 2.8 | 3.0 | Yes |
| 10:00:15 | | | | |
| 2024-09-30 | 80 | 3.5 | 3.7 | Yes |
| 10:45:20 | | | | |
| 2024-09-30 | 65 | 1.0 | 1.1 | No |
| 11:15:50 | | | | |

In this table, “Humidity Level” represents the measured humidity in the environment, while “Predicted Deformation” is the value generated by the SVR model predicting how much the polymer may deform at that humidity level. “Alignment Deviation Detected” is the observed misalignment based on image analysis, and “Recalibration Triggered” indicates whether the system initiated recalibration based on the predicted or observed deviation. By providing such detailed insights, this AI implementation allows operators to manage the alignment process more effectively, ensuring consistent precision despite environmental changes.

Step 306 performs a Tool Load Analysis. In step 306, the system uses load sensors to monitor load levels on microdevice holders. In Step 306, the system logs changes in load when microdevices are added or removed. If load variability exceeds allowable margins, initiate an alignment verification using a test transfer with sacrificial structures to determine if recalibration is required.

The AI implementation for Step 306 involves using a machine learning algorithm, such as a Random Forest Regressor, to analyze tool load data and predict when load variability may impact alignment accuracy. Random Forest is a robust choice for this application due to its ability to handle complex relationships between input features, such as load changes, and their impact on alignment, making it well-suited to provide accurate predictions about the system's load stability.

The data used for this AI implementation comes from load sensors that monitor the weight and distribution on microdevice holders in real-time. This data includes readings from multiple points on the microdevice holder, detailing variations in load when microdevices are added or removed. Historical load data is also used to train the Random Forest model, allowing the algorithm to learn patterns that indicate when load variability is outside of the acceptable range for alignment accuracy. Additional data, such as the number of microdevices being loaded, their distribution across the holder, and any deviations from normal conditions, are also used as input features.

An example result produced by this AI implementation might be a warning indicating that the current load variability exceeds the predefined threshold for stable alignment. For instance, the Random Forest model might predict that the load distribution is uneven enough to affect alignment by more than 5 micrometers, triggering an alert for further action. Based on this result, the system could initiate a test transfer using sacrificial structures to verify whether recalibration is required to correct the alignment.

The results of this analysis can be fed forward to improve the entire system by enabling adaptive load management. If the model predicts significant load variability that could cause misalignment, the system could automatically adjust the loading sequence, redistribute the load to balance it, or recommend an alignment verification before proceeding. By continuously learning from each load analysis, the Random Forest model becomes more accurate in predicting the impact of load changes, helping to minimize alignment issues and prevent production delays. This proactive approach ensures that misalignments are detected and corrected early, reducing downtime and enhancing overall system efficiency.

An example table of results produced by the AI could look like this:

| | | | Predicted | |
|---|---|---|---|---|
| | Load | Load | Alignment | Recalibration |
| | Level | Variability | Impact | Triggered |
| Timestamp | (kg) | (%) | (μm) | (Yes/No) |
| 2024-09-30 | 3.5 | 1.2 | 1.0 | No |
| 08:50:12 | | | | |
| 2024-09-30 | 4.2 | 5.5 | 5.2 | Yes |
| 09:05:30 | | | | |
| 2024-09-30 | 3.9 | 1.5 | 1.3 | No |
| 09:45:10 | | | | |
| 2024-09-30 | 4.8 | 6.1 | 5.8 | Yes |
| 10:15:40 | | | | |

In this table, “Load Level” represents the total load on the microdevice holder, while “Load Variability” shows how much the load has fluctuated compared to normal conditions. “Predicted Alignment Impact” indicates the potential deviation in alignment that the Random Forest model predicts based on the current load, and “Recalibration Triggered” specifies whether a recalibration step was recommended. Such a table helps operators and engineers to understand the impact of load variability on alignment accuracy and make informed decisions to maintain stability during the production process.

Step 307 performs a Material Fatigue Evaluation. In step 307 the system uses strain gauges on support structures to identify any bending or deformation. In step 307 the system compares current structural integrity against baseline measurements. If fatigue is detected, initiate a recalibration routine or a recommendation for maintenance.

The AI implementation for Step 307 uses a Principal Component Analysis (PCA) model to evaluate material fatigue by analyzing strain gauge data collected from support structures. PCA is suitable for this task because it can reduce the dimensionality of complex strain data and identify the most significant variations that contribute to material fatigue. By detecting patterns of deformation, PCA can help determine whether the integrity of support structures is being compromised over time, which is crucial for maintaining precise alignment during the manufacturing process.

The data used for this AI implementation comes from strain gauges positioned at multiple points on the support structures. These gauges continuously monitor factors such as bending, deformation, and strain distribution. Historical baseline measurements, taken when the system was known to be operating under optimal conditions, are also used to establish reference points. The data includes readings on strain levels in different directions and their rates of change over time, providing a comprehensive view of the structural integrity.

An example result produced by the PCA analysis might be a determination that a particular support structure is undergoing abnormal deformation. The PCA model could identify a principal component that indicates an increasing level of strain in a specific area, suggesting that fatigue is developing. This result would prompt the system to either initiate recalibration or recommend maintenance before the deformation leads to significant alignment errors. The ability to predict fatigue and prompt maintenance ensures that misalignment and potential system failures are avoided.

The results of the PCA analysis are fed forward to improve the entire system by enabling predictive maintenance and reducing unplanned downtime. For example, if the PCA model identifies that the material fatigue in a specific structural element is progressing beyond acceptable limits, maintenance can be scheduled proactively rather than reactively. The data from the strain gauges and the fatigue predictions can also be used to update the model, allowing it to learn from new data and improve the accuracy of its predictions. Additionally, by keeping track of which structural areas are most prone to fatigue, engineers can improve future design iterations of the system to enhance durability and reduce the likelihood of fatigue-induced issues.

An example table of results produced by the AI could look like this:

| | | Principal | Fatigue | |
|---|---|---|---|---|
| | Strain | Component | Risk | Maintenance |
| | Level | (Deformation | Level | Recommended |
| Timestamp | (με) | Index) | (%) | (Yes/No) |
| 2024-09-30 | 150 | 1.2 | 20 | No |
| 09:00:00 | | | | |
| 2024-09-30 | 300 | 2.8 | 65 | Yes |
| 10:15:30 | | | | |
| 2024-09-30 | 180 | 1.5 | 30 | No |
| 11:45:10 | | | | |
| 2024-09-30 | 350 | 3.1 | 70 | Yes |
| 13:20:45 | | | | |

In this table, “Strain Level” represents the measured strain in microstrain units (με), while “Principal Component (Deformation Index)” indicates the significant factors derived from PCA that suggest deformation in the structure. “Fatigue Risk Level” shows the probability of material fatigue occurring, based on the PCA analysis. “Maintenance Recommended” specifies whether a proactive maintenance step should be taken based on the risk level. This structured information helps operators prioritize maintenance actions, prevent alignment issues, and ensure the reliability of support structures in the system.

Step 308 performs a Calibration Validation. In step 308, the system validates the tool's calibration by performing sacrificial test transfers and comparing marks on the system substrate to expected positions. In step 308, the system tracks deviations to identify trends indicating incorrect or degraded calibration.

The AI implementation for Step 308 employs a K-means clustering algorithm to validate tool calibration by analyzing sacrificial test transfers and identifying deviations from expected alignment positions. K-means is a suitable choice for this step because it can group calibration data into clusters, distinguishing between properly calibrated and deviated marks based on their spatial distribution. This allows the system to quickly identify trends in tool performance and determine whether the calibration is consistent or if it has degraded over time.

The data used for this AI implementation includes the positions of alignment marks produced by sacrificial test transfers on the system substrate. This data is captured using high-resolution cameras that record the exact coordinates of the marks. Historical calibration data, including expected positions for these marks, is also used to train the K-means algorithm. Each set of alignment marks from sacrificial transfers is then compared to these reference positions, and any deviations are recorded. Additional data includes information on environmental conditions such as temperature, load variability, and tool wear, which could contribute to calibration drift.

An example of results from the K-means clustering analysis could be the identification of a cluster of alignment marks that are deviating significantly from the expected position. The algorithm may classify these marks into a separate cluster that represents degraded calibration, indicating that the tool's alignment has shifted beyond acceptable limits. This information is critical because it helps the system determine whether recalibration is required before proceeding with further production steps. For example, if a set of alignment marks falls within the cluster representing degraded calibration, the system can trigger a recalibration routine to restore accuracy.

The results from this analysis can be fed forward to improve the entire system by identifying patterns in calibration degradation and addressing them proactively. By continuously tracking and clustering calibration data, the system can predict when recalibration might be needed in the future, based on historical trends. This predictive capability allows for scheduled maintenance rather than reactive adjustments, reducing downtime and enhancing the stability of the alignment process. Additionally, if the algorithm identifies repeated deviations that correlate with specific environmental or operational conditions, the system can make adjustments to those conditions (e.g., temperature control) to mitigate their impact on calibration.

An example table of results that the AI implementation might produce is shown below:

| | Test | | | | |
|---|---|---|---|---|---|
| | Transfer | | | Cluster | Recali- |
| | Mark | Expected | | Assignment | bration |
| | Position | Position | Deviation | (Calibrated/ | Triggered |
| Timestamp | (mm) | (mm) | (mm) | Degraded) | (Yes/No) |
| 2024-09-30 | (5.10, | (5.00, | 0.22 | Calibrated | No |
| 09:30:00 | 3.20) | 3.00) | | | |
| 2024-09-30 | (5.50, | (5.00, | 0.65 | Degraded | Yes |
| 10:00:15 | 3.80) | 3.00) | | | |
| 2024-09-30 | (5.05, | (5.00, | 0.11 | Calibrated | No |
| 11:15:20 | 3.10) | 3.00) | | | |
| 2024-09-30 | (5.60, | (5.00, | 0.75 | Degraded | Yes |
| 12:45:30 | 4.00) | 3.00) | | | |

In this table, “Test Transfer Mark Position” represents the actual coordinates of alignment marks from the sacrificial test transfer, while “Expected Position” indicates the intended reference coordinates. “Deviation” shows the difference between these positions, and “Cluster Assignment” represents whether the alignment falls within a calibrated or degraded category based on K-means clustering. “Recalibration Triggered” indicates whether a recalibration was initiated based on the detected deviation. By monitoring these metrics, the system can maintain calibration accuracy and prevent errors that could lead to misalignment during production.

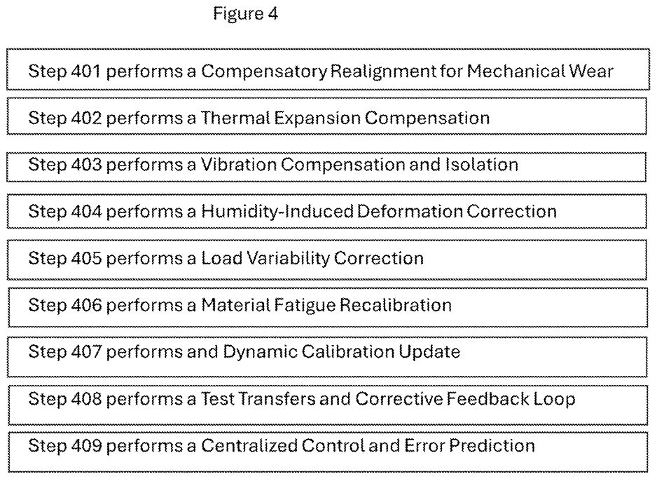

In FIG. 4, the system uses a Method for Error Correction and Fixing Compounded Errors. This method detects errors, initiates corrective actions, and ensures that multiple sources of errors are addressed collectively, mainly when they interact or compound.

In FIG. 4, the system deploys a Step-by-Step Method for Error Correction and Fixing. The system performs an Error Detection Feedback Loop. The system creates a feedback loop for each error detection step outlined in the error-checking method. If an error is detected, the system logs its severity and determines if it requires immediate action or can wait until a maintenance period.

Step 401 performs a Compensatory Realignment for Mechanical Wear. Step 401 adjusts the movement path based on detected discrepancies if wear is detected. In step 401, the system introduces micro-adjustments to the motor or actuator travel distance to account for the wear, effectively recalibrating without interrupting production.

Step 402 performs a Thermal Expansion Compensation. In Step 402, temperature data is used to predict the thermal expansion or contraction of the tooling components. Step 402 then applies for real-time compensation by adjusting the alignment positions based on the thermal profile, ensuring the alignment marks on the microdevice holder and system substrate stay consistent. In extreme cases, pause production until optimal temperatures are restored.

Step 403 performs a Vibration Compensation and Isolation. Step 403 checks if vibration is detected during a critical alignment process and pauses the operation. Step 403 uses a secondary stabilizing mechanism to isolate vibrations or wait for vibrations to subside before recalculating alignment. Step 403 then performs an additional test transfer to ensure stability before proceeding.

Step 404 performs a Humidity-Induced Deformation Correction. In Step 404, the system determines if humidity-induced changes are detected, initiates a recalibration process for the alignment marks on the polymer. Step 404 applies corrections by recalculating the alignment positions to account for polymer deformation. Optionally, Step 404 adjusts humidity levels in the production environment to minimize future deformation.

Step 405 performs a Load Variability Correction. In Step 405, if load variability is detected, the system uses additional balancing actuators to maintain the stability of the microdevice holder. Step 405 adjusts the calculated alignment mark positions to compensate for changes in load weight. Step 405 initiates a new sacrificial transfer if the load shifts during production to validate the system's positioning before the actual microdevice transfer.

Step 406 performs a Material Fatigue Recalibration. If material fatigue is detected, Step 406 applies corrective offsets to any detected deformations in support structures. If deformation exceeds a safe threshold, Step 406 suspends production until structural components are repaired or replaced. Ste 406 conducts a new baseline calibration once material fatigue issues are resolved to reestablish reference values.

Step 407 performs a Dynamic Calibration Update. Step 407 introduces a dynamic recalibration module that updates tool calibration based on the cumulative effect of multiple detected errors. This module performs on-the-fly adjustments, considering all active error sources (e.g., a combination of wear, vibration, and thermal expansion). Step 407 executes a test transfer using sacrificial structures to verify cumulative correction accuracy if compounded errors are detected—such as when wear and vibration simultaneously impact alignment—adjust the alignment protocol to address both issues holistically rather than in isolation.

Step 408 performs a Test Transfer and Corrective Feedback Loop. Before the actual transfer of microdevices, Step 408 conducts test transfers with sacrificial structures to evaluate alignment errors. Step 408 analyzes the test transfer marks and compares them against expected positions. If errors are detected, update parameters like temperature, load distribution, or vibration damping to correct the alignment process. Step 408 repeats the test transfers if significant deviations persist to ensure accuracy before proceeding with the device transfer.

Step 409 performs Centralized Control and Error Prediction. Step 409 implements a centralized control system that monitors all contributing factors (temperature, humidity, vibration, wear). Step 409 may use AI algorithms to predict potential error scenarios before they occur, enabling proactive recalibration or adjustments. Step 409 may cross-reference data from all sensors to identify compounded errors, such as simultaneous thermal expansion and mechanical wear, and determine a composite correction strategy.

By employing this comprehensive system method, individual sources of alignment drift are identified and corrected, and compounded errors are also addressed. This ensures that the entire production process remains robust and accurate, significantly enhancing the quality and reliability of the integrated optoelectronic systems.

The embodiment involving multiple distributed sacrificial reference points across the microdevice holder and system substrate could be utilized in FIG. 3 during the “Test Transfer Step.” Distributed sacrificial points are used across multiple substrate regions instead of transferring all the sacrificial structures to a single area. This enables the system to detect regional misalignments caused by localized effects such as non-uniform thermal expansion. In doing so, it ensures the calibration for the entire system is robust, allowing for fine-tuned adjustments to be made for each region before proceeding to the “Actual Transfer Step.”

In the embodiment using real-time feedback from sensors such as interferometric sensors and optical encoders, FIG. 4 could integrate this during the “Monitor Alignment During Transfer” step. The real-time sensing data from these sensors is used continuously as the transfer occurs, allowing the system to dynamically adjust to environmental factors such as vibrations or mechanical disturbances. If an error is detected mid-process, the system can momentarily pause the transfer and recalibrate, ensuring the final positioning remains highly accurate.

The laser-generated alignment marks on a temporary polymer layer could be applied during the “Pre-Transfer Calibration Step” in FIG. 3. The system can verify and adjust its calibration by using a laser to create precise alignment marks without transferring any physical microdevices. This approach helps to reduce wear on the mechanical components. It ensures the positioning accuracy is validated before proceeding with the physical microdevice transfer in the subsequent steps, enhancing overall alignment reliability.

The non-contact laser triangulation method could be used in FIG. 4 during the “Initial Position Verification Step.” Instead of physically interacting with the sacrificial structures, laser triangulation sensors are used to assess the initial alignment by scanning the marks on both the holder and system substrate. This verification ensures that no direct physical contact or additional load is placed on the tool during the initial setup, thereby reducing the chance of drift from tool movement before beginning the microdevice transfer process.

The embodiment using heat-sensitive material on the system substrate could be utilized during the “Alignment Error Detection Step” in FIG. 3. In this step, the alignment system simulates a transfer by applying minimal heat to a temperature-sensitive polymer layer. The resulting heat marks provide visual feedback about the positioning accuracy. This allows the system to adjust before proceeding to the complete microdevice transfer in the following steps. This ensures that any detected misalignment is corrected without direct material transfer, which could lead to tool recalibration issues.

The holographic projection for virtual alignment marks can be utilized in FIG. 4 during the “Alignment Confirmation Step.” The holographic system projects virtual alignment grids onto the microdevice holder and the system substrate in this step. A sensor array then captures These virtual marks, providing precise feedback on the current alignment status. By virtually confirming alignment, the system reduces physical wear and prevents tool drift before the final transfer step, improving calibration stability and process reliability.

The simultaneous calibration using load-distributed sacrificial transfers could be applied in FIG. 3 during the “Partial Sacrificial Transfer and Load Calibration Step.” In this step, the system transfers only part of the microdevices to test how the tool reacts to changes in load. Differential strain gauges are also used to monitor any load-induced deformation. After analyzing the effect on positioning accuracy, recalibrations are made to account for these load effects before proceeding to the “Full Transfer Step,” ensuring that the entire substrate can be aligned accurately without encountering issues from load variability.

1. A method to measure an alignment error, the method comprising:
having a pattern of polymers on a system substrate;
having an additional pattern under or around a polymer to facilitate a measurement of an alignment error;
creating marks by a microdevice holder/substrate on the polymer; and
using the location of markings relative to the polymer pattern or the additional pattern to calculate the alignment error.

2. The method of claim 1, wherein the pattern has different shapes and configurations.

3. The method of claim 1, wherein the polymer is a continuous film on top of a defined pattern.

4. The method of claim 1, wherein the polymer is eliminated where the marking exists on a microdevice.

5. The method of claim 1, wherein the polymer is adhesive to hold the markings.

6. The method of claim 1, wherein the method further comprises correcting an alignment drift caused by an environmental humidity during a microdevice transfer, which further comprises;
continuously monitoring the environmental humidity using humidity sensors to detect variations affecting materials used in an alignment, such as polymers on the system substrate;
capturing alignment marks using optical sensors to determine if the alignment drift has occurred due to expansion or contraction of a polymer layer; and
recalculating and adjusting alignment parameters in response to detected changes, thereby compensating for humidity-induced positional discrepancies and maintaining alignment an accuracy during the microdevice transfer.

7. The method of claim 1, wherein the method includes a method for correcting alignment errors due to load variability during the microdevice transfer, comprises;
continuously monitoring load distribution on the microdevice holder using load sensors during partial sacrificial transfers to detect any changes that may impact an alignment accuracy; capturing alignment marks on the microdevice holder and the system substrate using non-contact sensing methods to determine load-induced drift, and
recalibrating the alignment of the positioning system in response to load changes to compensate for any detected discrepancies and balancing the load to reduce positional instability and proceeding with complete the microdevice transfer will be done only once the alignment has been verified and corrected.

8. The method of claim 1, wherein the method includes a method for maintaining the alignment accuracy during the microdevice transfer to compensate for material fatigue, comprises;
continuously monitoring the structural components of the positioning system using strain gauges to detect signs of material fatigue; capturing alignment marks on the microdevice holder and the system substrate and comparing them against reference positions to detect any positional drift caused by deformation of the structural components; and
applying corrective offsets to the alignment to counteract the effect of fatigue-induced deformation; and
if fatigue exceeds acceptable thresholds, suspending the microdevice transfer process for maintenance and recalibration.

9. The method of claim 1, wherein the method includes a method for maintaining the alignment accuracy through dynamic tool calibration during the microdevice transfer, comprises;
capturing alignment marks on the microdevice holder and the system substrate before and during the microdevice transfer process to validate tool calibration, comparing detected alignment positions against predefined reference points to identify calibration errors, and
initiating real-time calibration corrections using sacrificial structures to detect deviations, adjusting the alignment tool's parameters to correct discrepancies, and repeating the test transfer process until the alignment accuracy is restored before proceeding with the actual the microdevice transfer.

10. The method of claim 1, wherein the method includes a method for correcting alignment drift due to mechanical wear and tear during the microdevice transfer, comprises;
performing a self-diagnostic analysis of positioning system components, such as motors, actuators, and guide rails, to assess mechanical wear; capturing alignment marks on both the microdevice holder and the system substrate using non-contact sensing methods to determine any positional discrepancies, and
applying incremental adjustments to the movement path of the positioning system based on detected deviations, thereby compensating for wear-related inaccuracies and
continuously recalibrating the alignment tool to ensure alignment precision throughout the microdevice transfer process.

11. The method of claim 1, wherein the method includes a method for compensating for thermal expansion and contraction effects during the microdevice transfer, comprises;
continuously monitoring the temperature of the positioning system's structural components using temperature sensors to detect temperature variations; capturing alignment marks on the microdevice holder and the system substrate to determine any positional changes caused by thermal expansion or contraction; recalculating and adjusting the alignment parameters dynamically in response to detected thermal changes to ensure the alignment accuracy, and
applying compensatory offsets to correct for temperature-induced drift during the microdevice transfer process.

12. The method of claim 1, wherein the method includes a method for mitigating misalignment caused by mechanical vibrations during the microdevice transfer, comprises;
continuously monitoring vibration levels using accelerometers to detect mechanical disturbances, pausing the alignment process if vibrations exceed a predefined acceptable level, and
capturing alignment marks on the microdevice holder and the system substrate only once vibration levels stabilize, ensuring that adjustments to the positioning system are made based on accurate, vibration-free readings, and resuming the alignment and transfer process once vibrations are determined to be within acceptable limits.

13. A method for calibrating an alignment of microdevices during manufacturing, comprising:
performing a pre-transfer calibration of an alignment tool, wherein an alignment reference is established between a microdevice holder and a system substrate;
executing a test transfer involving sacrificial structures positioned on a microdevice substrate, wherein the said sacrificial structures are transferred to a test area on the system substrate;
evaluating an alignment error based on a comparison of transferred sacrificial structure positions relative to predefined reference points on the system substrate;
adjusting the alignment tool based on an alignment error determined from the said evaluation to correct any positional discrepancies between the microdevice holder and the system substrate; and
transferring the microdevices from the microdevice holder to the system substrate following the calibration, wherein the said transfer is performed using recalibrated alignment settings.

14. (canceled)

15. A method for monitoring and correcting an alignment during a microdevice transfer, comprising;
verifying an initial position of microdevices on a microdevice holder relative to alignment marks on a system substrate;
continuously monitoring the alignment during the microdevice transfer process using real-time sensing data;
detecting any deviations from the intended alignment by comparing the real-time positions of alignment marks on the microdevice holder and the system substrate;
determining corrective actions to compensate for detected alignment errors during the transfer;
performing compensatory adjustments to an alignment tool or positioning system, the microdevice holder, the system substrate, or any combination thereof, based on the detected deviations to maintain a precise alignment; and
completing the transfer of microdevices to the system substrate following said adjustments, enabling proper and accurate placement of all microdevices.

16. (canceled)
